(19) United States
(12) Patent Application Publication
(10) Pub. No.: US 2004/0245617 A1
(43) Pub. Date: Dec. 9, 2004

(54) Dense multichip module

(75) Inventors: Philip Damberg, Cupertino, CA (US); Ilyas Mohammed, Santa Clara, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA

(21) Appl. No.: 10/839,303

(22) Filed: May 5, 2004

Related U.S. Application Data
(60) Provisional application No. 60/468,183, filed on May 6, 2003.
(60) Provisional application No. 60/490,802, filed on Jul. 28, 2003.

(51) Int. Cl. H01L 21/48; H01L 23/52

(52) U.S. Cl. 257/686; 438/109; 257/782; 438/118

(57) ABSTRACT

A memory chip module includes multiple stacks of memory chips arranged on a base panel. The chip stacks desirably are arranged in rows symmetrical about a central plane and define a channel in a central region of the base panel. Control chips such as a register chip associated with the memory chips in the stacks can be provided in this central region of the base panel. Desirably, the base panel is surface-mountable on a circuit board. The module provides high memory chip packing density, effective cooling and short, balanced signal lines between the control chip and the memory chip stacks.

### CROSS-REFERENCE TO RELATED APPLICATIONS

The present application claims the benefit U.S. Provisional Patent Application Nos. 60/490,802, filed Jul. 28, 2003; and 60/468,183, filed May 6, 2003, the disclosures of which are hereby incorporated by reference herein.

### BACKGROUND OF THE INVENTION

The present invention relates to semiconductor chip packages and assemblies.

Semiconductor chips are generally planar elements, typically rectangular solid elements, having a length and width, commonly referred to as “horizontal” dimensions, many times greater than their thickness or vertical dimensions. Chips are typically provided in packages which physically protect the active semiconductor chip itself, and which facilitate mounting the chip to a circuit board. Most commonly, the chips are mounted on a circuit board so that the horizontal dimensions of the chip lie in a plane parallel to the plane of the top surface of the circuit board.

It is generally desirable to reduce the area of the circuit board surface occupied by a chip package. Minimizing the area occupied by a chip package helps to make the overall assembly more compact and also allows for the use of shorter traces on the circuit board, which helps to limit signal propagation delays. This, in turn, facilitates operation of the circuit formed by the packaged chip and other components at relatively high speeds. It is generally also desirable to minimize the height or vertical extent of a chip package. However, in certain applications, the height of the package is less critical. For example, in some applications, components other than the chip package mounted on the circuit board project upwardly from the circuit board, so that the top surface of the circuit board cannot be mounted close to other components in any event, regardless of the chip package height. In other applications, the top surface of the circuit board must be spaced from adjacent circuit boards or other elements of the assembly by a certain minimum distance to provide adequate space for coolant flow.

Packages referred to as “chip scale packages” occupy an area of the circuit board top surface only slightly larger than the area of the chip itself. Stated another way, the horizontal dimensions of such a package are equal to or just slightly larger than the horizontal dimensions of the chip. However, even when chip scale packages are employed, or where unpackaged “bare” semiconductor chips are mounted directly on a circuit board, each chip still occupies an area of the circuit board surface at least equal to the area of the chip itself.

To further conserve area on the circuit board, chips can be packaged in a stacked arrangement, with chips superposed on one another. Such stacked package may include a plurality of units, each unit incorporating one chip or a few chips, and a packaging structure similar to those used in ordinary chip packages. The units are typically mounted to the circuit board in much the same manner as a conventional chip package. Stacking allows several chips to occupy an area on the top surface of the circuit board, which may be less than the aggregate area of the individual chips themselves. Merely by way of example, designs for stacked packages are shown in U.S. Pat. Nos. 5,861,666; 5,148,265; 6,465,893 and 6,225,688, and in co-pending, commonly assigned U.S. patent application Ser. Nos. 10/267,450 and 10/454,029. The disclosures of said patents and said co-pending applications are hereby incorporated by reference herein. Although the height or vertical dimensions of a stacked package typically are somewhat greater than the corresponding dimensions of a single-chip package, this does not pose a serious problem in some applications. Stacked chip packages can be used, for example, in packaging memory chips.

Chip packages can be mounted to circuit boards by a variety of techniques as, for example, by pins on the package engaged in a socket on the circuit board, or by soldering leads projecting from the package into vias extending through the circuit board. However, many modern chip packages are arranged for surface-mounting. The package is provided with terminals on a bottom surface, typically in the form of metallic pads, and the circuit board has a corresponding array of contact pads on its top surface. The package is disposed with its bottom surface facing downwardly and confronting the top surface of the circuit board, and the pads are bonded to one another by a bonding material, most typically a solder. Surface-mounting provides a compact arrangement with non-impedance electrical and avoids the need for additional structures which can complicate the layout of traces on the circuit board.

Memory chips such as dynamic random access memory (DRAM) and electrically erasable programmable read-only memory (EEPROM) or flash memory chips commonly are used in sets including a plurality of memory chips which are substantially identical with one another in conjunction with other chips, referred to herein as “control chips,” which facilitate operation of the memory chips. For example, DRAM chips commonly are employed in conjunction with a chip referred to as a register chip. The register chip receives information such as read or write commands and addresses and directs this information to the actual DRAM chips. In certain applications, the control chips used with DRAM chips also include a local clock chip, typically a phase lock loop (PLL) device. Other chips such as a non-volatile memory, typically an EEPROM, also may be provided in a module or assembly which includes DRAM chips.

Memory chips and the control chips used therewith commonly are provided in pre-assembled modules so that the module can be mounted to a circuit board as a unit. For example, DRAM chips commonly are provided in a dual in-line memory module (DIMM). A DIMM includes a module circuit board in the form of an elongated strip having terminals along one edge. DRAM chips are mounted in an array extending along the length of the module circuit board, and the data input and output connections of the DRAM chips are connected to some of the terminals on the edge of the circuit board. Other terminals are connected to the control chips as, for example, to one or more register chips mounted on the module circuit board. The module can be mounted to a larger circuit board, commonly referred to as a motherboard, by engaging the terminal-bearing edge of the module circuit board with an edge connected mounted on the motherboard.

A DIMM occupies substantial space. The DIMM module circuit board typically lies in a plane perpendicular to the plane of the motherboard. The entire width of the module circuit board projects vertically upwardly from the motherboard. This requires that the motherboard be spaced at least that distance from an adjacent overlying circuit board or housing. The edge connector adds cost and bulk and can cause reliability problems. Further, the DIMM architecture leads to considerable signal propagation delays. Because the DRAM chips are disposed side-by-side along the length of the module circuit board, the traces on the module circuit board connecting the control chips to the DRAM chips must also extend along the length of the module circuit board. Even where the control chips are provided adjacent the mid-point of the length, the traces extending to the chips at the end of the circuit board must have lengths at least equal to about one-half the length of the module circuit board, i.e., several centimeters. If all of the traces are made with their minimum physically possible lengths, the traces extending to the DRAM chips near the ends of the module circuit board will be much longer than traces extending to other DRAM chips, near the middle of the module board and near the control chips. In this arrangement, signals passing from the control chip to the DRAM chips near the middle of the module board will encounter significantly shorter signal propagation delays than signals passing from the control chip to the remote DRAM chips, at the ends of the module board. Although the signal propagation delays can be balanced by forming the shorter traces with serpentine bends to introduce added length, the speed of the system is still limited by the longest traces. Moreover, the need for extensive serpentine routing complicates layout of the module board and can require additional layers of traces.

Thus, despite the considerable efforts devoted to packaging memory chips in the art heretofore, there are still significant needs for improvements in memory chip modules. There are corresponding needs for improvements in multi-chip modules for other applications.

### SUMMARY OF THE INVENTION

One aspect of the invention provides multi-chip modules. A module according to this aspect of the invention desirably includes a base circuit panel having top and bottom surfaces and external terminals adapted for mounting said base circuit panel to an external circuit board, said base panel also having traces. The base panel includes a plurality of peripheral regions and a central region disposed between the peripheral regions. A module according to this aspect of the invention desirably includes four or more chip stacks. Each chip stack includes a plurality of chips superposed on one another. The chip stacks preferably are mounted on the top surface of the base panel in the peripheral regions of the base panel. For example, the peripheral regions may include two side regions disposed on opposite sides of the central region, and the chip stacks may be arranged in these two side regions.

The module desirably includes a first control chip mounted to the central region of the base panel. The traces on the base circuit panel desirably include first control chip interconnect traces connecting the first control chip to each of said chip stacks. Desirably, the chip stacks are arranged on the base panel so that each of the chip stacks directly borders the central region of the base panel, i.e., so that it is possible to draw a straight line in the plane of the base panel between each chip stack and the central region without passing through any other chip stack. Desirably, the ratio between (i) the horizontal distance from the center of a particular chip stack to the center of the first control chip and (ii) the horizontal distance from the center of a any other chip stack to the center of the first control chip is about 3:1 or less, and preferably about 2:1 or less.

The traces on the base panel desirably include separate traces extending between the first control chip and each one of the chip stacks. The arrangement of chip stacks and control chips on the base panel makes it relatively easy to provide relatively short traces of equal lengths to all of the chip stacks without extensive serpentine routing. Moreover, the entire module can be quite compact, so that it when it is mounted on a motherboard, the module occupies only a small volume above the plane of the motherboard has a relatively small height above the motherboard. Desirably, the base panel includes external terminals for mounting and connecting the module to an external substrate such as a motherboard. Preferably, the external terminals are arranged to mount the base panel in substantially horizontal orientation, so that the bottom surface of the base panel confronts the top surface of the circuit board. For example, the external terminals may be pins or pads adapted for surface mounting. The module may include additional chips mounted to the bottom surface of the base panel. For example, where the chips in the stacks are memory chips, additional memory chips may be mounted below the base panel in alignment with the stacks. The additional chips desirably are mounted in regions of the bottom surface which are not occupied by the external terminals. As explained further below, such additional chips do not add to the overall height of the module when the module is mounted to the circuit board. The chips in the stacks, and the additional chips, where used, all may be provided as substantially identical packaged chips, and the module desirably can be assembled using conventional surface-mounting techniques.

A module according to a further aspect of the invention includes a base panel having a top surface, said base panel including a central region and peripheral regions including two side regions disposed on opposite sides of said central region. The module according to this aspect of the invention also includes a plurality of chip stacks, the chip stacks being arranged in a first row including at least two chip stacks projecting upwardly from the top surface in the first side region and a second row of at least two chip stacks projecting upwardly from the top surface in the second side region. The second row of chip stacks extends generally parallel to the first row, and thus the rows of chip stacks define a channel extending across the top surface of the central region in a channel direction generally parallel to the rows. The channel provides space between the chip stacks for coolant access. Moreover, control chips can be mounted on the central region of the panel, and housed in the channel.

A further aspect of the invention provides an assembly including a plurality of modules. Each module includes a base panel having top and bottom surfaces and a plurality of chip stacks mounted on the top surface of the base panel. The individual modules preferably are configured as discussed above in accordance with the foregoing aspects of the invention. The assembly according to this aspect of the invention also includes interconnect elements physically connecting the base panels of the modules to one another so that modules are arranged in a vertically-extensive module stack with said base panels superposed over one another and with each base panel extending generally horizontally. The module desirably includes assembly terminals adapted for mounting the module stack to an external circuit board with the module stack projecting upwardly from the circuit board. Assemblies according to this aspect of the invention can provide even more compact mountings for large systems of chips such as, for example, large arrays of memory chips.

Still further aspects of the invention provide methods of making and mounting modules. Yet another aspect of the invention provides chip stacks having chip carriers with portions projecting from the edges of the stack curved out of the plane of the chip carrier. These projecting portions act as cooling fins on the sides of the chip stack. The projecting portions may be folded over to provide a compact heat transfer structure.

### BRIEF DESCRIPTION OF THE DRAWINGS

FIG. 1 is a diagrammatic top plan view of a module in accordance with one embodiment of the invention.

FIG. 2 is a diagrammatic bottom view of the module depicted in FIG. 1.

FIG. 3 is a fragmentary elevational view depicting the module of FIGS. 1 and 2 in conjunction with a circuit board.

FIG. 4 is a fragmentary, partially sectional, elevational view on an enlarged scale depicting the module and components of FIG. 3.

FIG. 5 is a diagrammatic top plan view of a module in accordance with a further embodiment of the invention.

FIG. 6 is a view similar to FIG. 5 but depicting a module according to yet another embodiment of the invention.

FIG. 7 a diagrammatic elevational view of a module stack according to a further embodiment of the invention.

FIG. 8 is a diagrammatic sectional elevational view depicting the module stack of FIG. 7.

FIG. 9 is a diagrammatic elevational view of a chip stack in accordance with a further embodiment of the invention.

FIG. 10 is a fragmentary sectional view depicting a portion of a component in the chip stack of FIG. 5.

FIG. 11 is a view similar to FIG. 9 but depicting a chip stack in accordance with a further embodiment of the invention.

### DETAILED DESCRIPTION

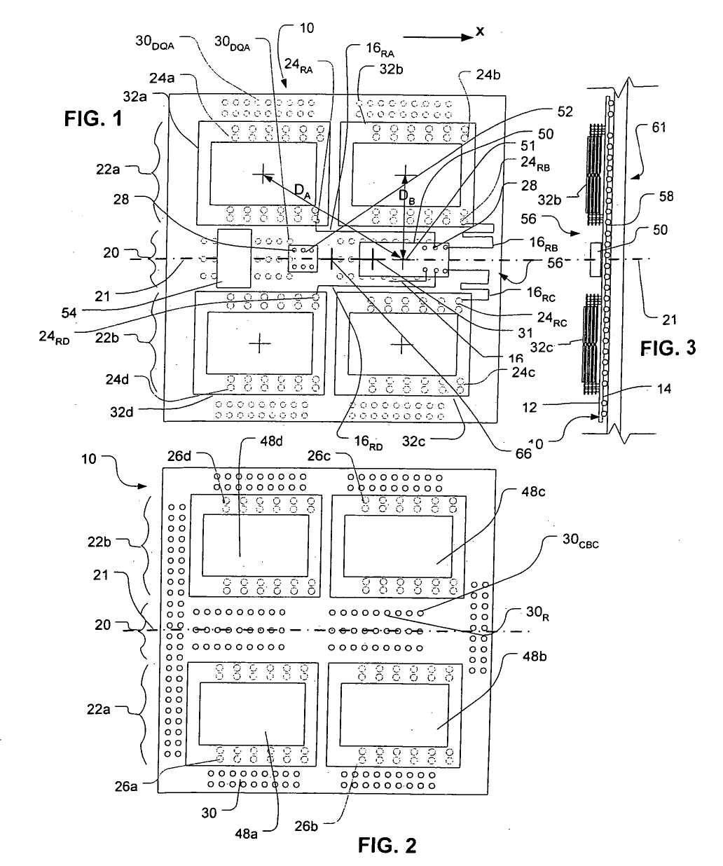

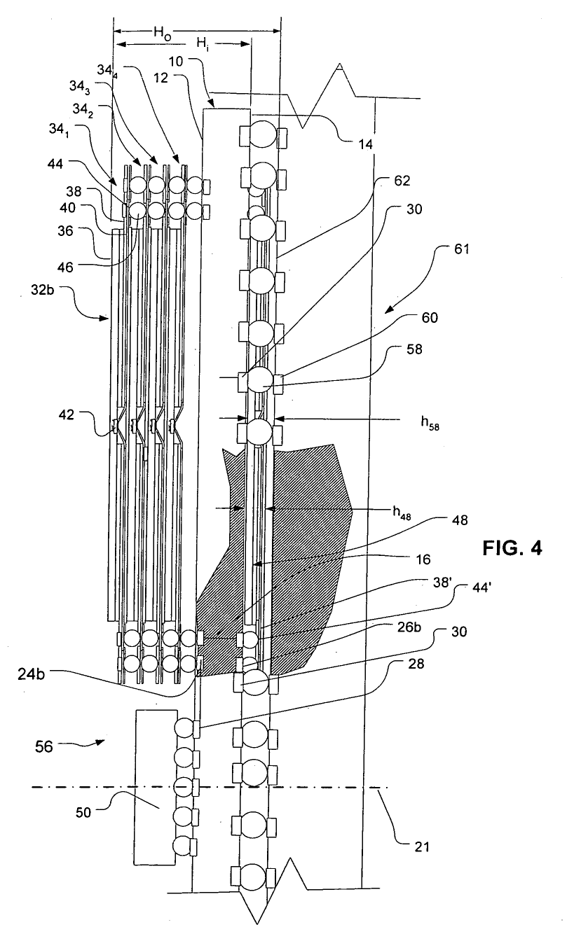

A module in accordance with one embodiment of the invention includes a base circuit panel 10 having a top surface 12 and an oppositely facing bottom surface 14. The base panel desirably is a multi-layer circuit panel, most typically including about four to eight layers of traces. A few traces 16 extending in generally horizontal directions parallel to the top and bottom surfaces of the panel are depicted in FIG. 1, whereas a few generally vertically extensive traces 16 are depicted in FIG. 4. These few traces are shown in diagrammatic form and are merely representative of the numerous horizontally and vertically extending traces incorporated in a real panel. These numerous traces are omitted for clarity of illustration. The vertically extending traces typically include horizontally extending portions in the various layers of traces interconnected to one another by conductive elements such as vias (not shown). The base panel may be formed using essentially any dielectric and conductive materials which can be incorporated in a rigid or flexible circuit panel. Merely by way of example, the dielectric materials incorporated in such a multi-layer circuit panel may include polymeric materials such as epoxies, polyimide, BT resin (bismaleimide triazine) and the like, with or without reinforcements such as fiberglass, carbon fibers, aramid fibers and the like. The base panel may also include inorganic dielectrics such as glass or alumina. The conductive traces and other conductive features of the panel may be formed from essentially any conductive material, most preferably a metal such as copper, gold or combinations thereof. The conductive features of the base panel may include elements such as conductive planes (not shown) carrying constant potentials such as ground or power potentials. The traces may be arranged to overlie or extend between such planes, with a layer of the dielectric layer extending therebetween so as to provide a stripline or ministrip controlled-impedance transmission line. Also, the traces may be arranged in pairs or sets to provide controlled impedance transmission lines.

The base panel is generally rectangular, and most preferably square in shape, as seen from the top or bottom. The base panel has a central region 20 extending along a medial plane 21 and peripheral regions consisting of a pair of side regions 22a and 22b disposed on opposite sides of the central region and, hence, on opposite sides of the medial plane. Thus, the central region 20 is generally in the form of an elongated strip extending in a first direction (towards the top and bottom of the drawing as seen in FIGS. 1 and 2), whereas the peripheral regions are in the form of similar elongated strips extending parallel to the central region.

The base panel has four sets of stack-mounting pads 24 disposed in the peripheral region. Two sets 24a and 24b lie in one side region 22a, whereas two other sets 24c and 24d are disposed in the opposite side region 22b. Only a few of the stack-mounting pads in each set are depicted in FIG. 1. The four sets of stack-mounting pads desirably are substantially identical with one another. Set 24a includes four rows of stack-mounting pads, these rows extending in directions parallel to the medial plane 21.

The base panel also includes four sets of additional chip-mounting pads 26a-26d (FIGS. 2 and 4) exposed at the bottom surface 14 of the panel. Each set of additional chip-mounting pads 26 is identical to a set of stack-mounting pads 24 and is disposed in alignment therewith. For example, additional chip-mounting pads 26a are arranged in a set identical to set 24a of stack-mounting pads, and pads 26a are aligned with pads 24a.

A set of control chip-mounting pads 28 is provided in the central region, these pads being exposed at the top surface 12 of the circuit panel.

The base panel further has external terminals 30 exposed at the bottom surface 14. The external terminals are provided in the central region, as well as in portions of the side regions outside of the areas occupied by the additional chip-mounting pads 26. External terminals 30 are in the form of pads adapted to receive solder balls or other conductive bonding materials for surface-mounting the base panel to a circuit board. The traces of the base panel serve to interconnect certain external terminals 30 with control chip-mounting pads 28, with certain stack-mounting pads 24, and with certain additional chip-mounting pads 26. The traces 16 also interconnect certain control chip-mounting pads 28 with certain stack-mounting pads 24 and with certain additional chip-mounting pads 26. The pattern of interconnections is further discussed below.

The module further includes four memory chip stacks 32. Each chip stack includes a plurality of semiconductor chips stacked one above the other. For example, chip stack 32b, seen in detail in FIG. 4, includes four individual units 34₁-34₄. Each unit 34 incorporates a semiconductor chip 36 mounted to a chip carrier 38, desirably formed from a thin dielectric layer. The chip carrier has traces 40 thereon, electrically connected to contacts 42 of the chip. Chip 36 is mounted in a central region of chip carrier 38. Traces 40 extend outwardly from the chip contacts 42 and terminate in pads 44 disposed near the periphery of the chip carrier. The pads 44 of each unit desirably are exposed at both sides of the chip carrier 38. That is, the chip carrier desirably has openings in alignment with the pads so that contact can be made with the pads from the top and the bottom, as seen in FIG. 4. In the particular arrangement illustrated, each chip carrier has four rows of pads 44, with two rows on one side of the chip carrier and two rows on the opposite side. However, the number of rows of pads and the placement of those rows on the chip carrier can be varied. The units desirably are substantially identical to one another and include identical chips and identical arrangements of pads.

The units are mechanically and electrically interconnected with one another by masses of bonding material in the form of solder balls 46 connecting corresponding pads on adjacent units. The solder balls 46 connect the corresponding pads of all of the units into vertical interconnect buses, so that each such bus extends through one pad of each unit. The interconnected units are thus held in a stack having chips 36 superposed on one another. The internal structure of the stack may be substantially as shown and described in co-pending, commonly assigned U.S. patent application Ser. No. 10/454,029 and co-pending, commonly assigned PCT International Application No. US02/32251, the disclosures of which are hereby incorporated by reference herein. As further disclosed in the aforementioned co-pending applications, the traces and related features on the various chip carriers desirably are arranged so that some contacts 42 of each chip, referred to as “common” contacts, are connected to the same vertical interconnect bus or stack of solder balls 46 as the corresponding contacts on other chips in the stack. Other contacts on each chip, referred to as “select” contacts, are connected differently, so that less than all of the corresponding select contacts are connected to an individual vertical bus. For example, in a stack incorporating four chips as seen in FIG. 4, the vertical data buses and interconnections on the individual chip carriers are arranged so that each vertical data bus associated with the select contacts is connected to a select contact on only one chip. These select buses can be used for signals involved in selectively actuating an individual chip in the stack.

The chip stacks 32 are mounted on stack-mounting pads 24 so that the stacks extend upwardly from the top surface 12 of the base panel 10. In the particular embodiment illustrated, the stacks are mounted by bonding the pads of the bottom unit directly to stack-mounting pads 24. As disclosed in the aforementioned co-pending applications, other arrangements can be employed. For example, a “translator” or small circuit panel can be provided at the bottom of each stack. Alternatively, the low-most unit 344 in the stack may have two sets of bonding pads: a top set in an arrangement corresponding to the pads on the other units in the stack, and a bottom set in a different arrangement, corresponding to the arrangement of the stack-mounting pads.

The chip stacks 32 are mounted in two rows, each incorporating two stacks. One row, consisting of stacks 32a and 32b, is disposed in the first peripheral region 22a of the base panel. The other row, consisting of stacks 32c and 32d, is disposed in the second, opposite peripheral region 22b. The rows extend in directions parallel to the medial plane 21 of the base panel. The chip stacks cooperatively define a stack centroid 66. The stack centroid is a point on base panel 66 such having coordinates in the horizontal directions in the plane of the base panel equal to the average of the coordinates of all of the chip stacks. In the particular embodiment illustrated, where the four chip stacks are equidistant from a horizontal line (not shown) through the midpoint of medial plane 21 and equidistant from the medial plane, centroid 66 is coincident with the midpoint of the medial plane (i.e., the center point of the base panel 10) and equidistant from the four chip stacks. Additional chips 48 are mounted to additional chip pads 26, so that the additional chips 48 are disposed on the bottom surface 14 of the base panel. Each additional chip is provided in a package which may be substantially identical to one of the units incorporated in the stack and, hence, may include a chip carrier 38′ and contact pads 44′ substantially as discussed above with reference to the units of the stack. The contact pads 44′ of the additional chips typically are arranged in substantially the same manner as the contact pads of the units in the stack, and, hence, each set of chip pads 26 desirably has substantially the same array configuration as a set of stack pads 24. Each additional chip may be disposed in the same orientation as the units of the stack. For example, stack 32b has each chip disposed with its contacts 42 facing downwardly; the contacts of additional chip 48 also face downwardly. Because each set of additional chip pads 26 is aligned with a set of stack pads, each additional chip 48 is disposed in alignment with one of the memory chip stacks 32. Each additional chip (including its package) desirably has a height, as mounted, of less than about 700 microns and desirably less than about 500 microns. That is, the maximum vertical dimension h₄₈ (FIG. 4) from the bottom surface 14 of the base panel to the lowest point of the additional chip desirably is less than 700 microns and more preferably less than about 500 microns. The external terminals 30 desirably are provided with solder balls 58 for mounting the base panel 10 to contact pads 60 on the top surface 62 of a circuit panel 61. As best appreciated with reference to FIG. 4, the additional chips 48b lie within the vertical space occupied by the solder balls 58. Thus, the height h₄₈ of each additional chip should be equal to or, preferably less than, the height h₅₈ established by the solder balls, i.e., the distance between the bottom surface 14 of the base panel and the top surface 62 of the circuit board. Typically, this height is about 1000 microns (1 mm) or less, and preferably about 700 microns or less.

As best appreciated with reference to FIGS. 1 and 3, memory stacks 32 are arranged in two rows, one such row being disposed in each side portion 22a and 22b of the base panel. Stacks 32a and 32b constitute one such row, whereas stacks 32c and 32d constitute another such row. These rows extend generally parallel to the medial plane 21 of the base panel and, hence, parallel to the direction of elongation of the strip-like central portion 20 of the base panel. The rows of stacks projecting upwardly from the base panel define a channel 56 extending along the central region 20.

The module further includes control chips 50, 52 and 54 disposed in the central region 20 of the base panel, overlying top surface 12. The control chips are connected to control chip pads 28. The control chips may be bare or unpackaged chips directly attached to the control chip pads 28. Preferably, however, the control chips are packaged in suitable packages having terminals distinct from the contacts of the chips themselves, and these terminals are attached to the control chip pads of the base panel. Merely by way of example, the control chips can be provided in packages such as ball-grid array packages, TAB packages or the like suitable for surface-mounting. Particularly preferred packages include packages of the type sold under the trademark pBGAG by Tessera, Inc., the assignee of the present application. Certain packages of this type allow movement of the package terminals relative to the contacts on the chip and hence provide very reliable connections despite changes in chip dimensions due to thermal cycling. The precise nature of the control chips will vary dependent upon the type of memory chips included in memory chip stacks 32. In the embodiment of FIGS. 1-4, the memory chips are DRAM chips and the control chips include a clock chip 54, such phase lock loop clock arranged to provide clock signals to all of the components of the module, a register chip 50 arranged to receive indications of commands to be performed by the module from outside of the module and to supply appropriate commands to the various memory stacks. The control chips desirably also include a programmable read-only memory, typically an electrically erasable programmable read-only memory, or EEPROM 52 The EEPROM may be used, for example, to store data representing the identity and/or configuration of the module so that this data can be read by the larger system in which the module is used.

The control chips 50, 52 and 54 are disposed within channel 56. The channel is desirably open at the top of the channel and, hence, provides a passageway along the central region for flow of coolant during operation.

The traces, external terminals and pads on the base panel desirably are arranged in a manner which provides short and well-balanced traces. Those vertical buses of the memory chip stacks which carry the actual user data signals (referred to as DQ and DQS signals) are connected to some of the stack-mounting pads 24. These stack-mounting pads are connected directly to some of the external terminals 30_{DQ}. These external terminals are located adjacent the stacks. Some of the external terminals 30_{DQ} are disposed in the peripheral region of the base panel, on the side of the stack remote from the medial plane 21. For example, some of terminals 30_{DQA}, seen in broken lines in FIG. 1. Other DQ terminals may be disposed in the central region 20 of the base panel, near the stack-mounting pads 24 connected to such terminals. For example, terminals 30_{DQA} located in the central region 20 are near stack 32 and pads 24a. Other external terminals which are connected to stack-mounting pads, such as terminals for ground (V_{SS}) and power (V_{DD}) are disposed in the same way. This arrangement provides short trace lengths and simple routing for these signals. As pointed out above, the additional chips 48 (FIGS. 2, 3 and 4) are disposed beneath the stacks 32, and the additional chip pads 26 are disposed in alignment with the stack-mounting pads. The additional chips are used to store error control bits, and the external terminals 30 which carry the control bit signals (CB) for each additional chip are disposed near that additional chip. For example, terminal 30_{CBC} is disposed near additional chip 48c and near additional chip pads 26c connected thereto.

The external terminals 30 connected to control chip-mounting pads 28, associated with control chips 50, 52 and 54, desirably are disposed near the control chips. For example, terminal 30_{R} (FIG. 2) is disposed in the central region of the base panel, near register chip 50. These external terminals carry signals such as address and control input and output (A0-A12, CKE0-1, BA0-1, CS0-1, /CAS, /RAS, /WE).

The stack-mounting pads which carry signals from the control chips, and particularly from register chip 50, desirably are disposed on those sides of the stacks nearest the medial plane. For example, mounting pad set 24d includes a subset of stack-mounting pads, including pad 24_{RD}, which are connected to register chip 50. The pads of this subset, including pad 24_{RD}, are disposed on the side of stack 32d closest to the medial plane. The corresponding subset of set 24a, including pad 24_{RA}, is disposed on the side of stack 32a closest to the medial plane. Similarly, the corresponding subsets of sets 24b and 24c stack-mounting pads 24_{RC} and 24_{RB} are also disposed close to medial plane 21. Therefore, these pads can be connected to the associated pads of set 28 at register chip 50 by relatively short traces symbolically indicated at 16_{RA}, 16_{RB}, 16_{RC} and 16_{RD}. The overall layout of the traces desirably is symmetrical or nearly symmetrical about medial plane 21. The layout provides short and readily balanced traces connecting the register chip to the stacks.

The arrangement facilitates providing balanced trace lengths having substantially equal signal propagation delays between the register chip 50 and the various stacks. Because register chip 50 is disposed near to end of central region 20, register chip 50 is further from stacks 32a and 32d than from stacks 32b and 32c. However, this difference in distance between the register chip and the various stacks is relatively small. One measure of this property can be obtained from the distances between the center of register chip 50 and the centers of the various stacks, as indicated by dimensions D_{A} and D_{B} in FIG. 1. Desirably, the ratio between the greatest center-to-center distance D_{A} and the smallest center-to-center distance D_{B} is less than about 2:1. This ratio, referred to herein as the center-to-center distance ratio, is substantially smaller than the corresponding ratio normally found in a conventional DIMM module.

Moreover, the ratio of theoretical straight line trace lengths between the control chip pads 28 associated with the register chip 50 and the various subsets of chip stack pads connected to the register chip typically is less than the center-to-center distance ratio. Pad 24_{RD} of set 24 is offset from the center of stack 32d in the direction parallel to medial plane 21 towards register chip 50. Likewise, pad 24_{RC} is also offset from the center of stack 32c in the same parallel direction parallel to the medial plane. Stated another way, the various subsets of chip stack pads connected to register chip 50 are offset from the centers of the associated stack in an offset direction as indicated by arrow X in FIG. 1. Thus, the centroid 31 of the array defined by these subsets (the point having horizontal coordinates equal to the average horizontal coordinates of the various pads of these subsets) is also offset in the same offset direction X from the centroid 66 of the chip stacks. This offset direction is the same as the direction between the centroid 66 of the chip stacks and the center of register chip 50. Thus, the array of stack mounting pads 24_{RA}, 24_{RB}, 24_{RC} and 24_{RD} connected to the register chip offset in the lengthwise direction of the central region, along the medial plane, in the same direction as register chip 50 is offset. The center 51 of register chip 50 lies nearly at the centroid 31 of this array stack-mounting pads connected to the register chip. This further reduces the trace lengths and aids in balancing the trace lengths.

Even with this configuration, the trace lengths between the register chip and the chip stack will differ somewhat if all of the traces are made with the shortest possible routing. Therefore, certain traces 16_{RB} and 16_{RC} may be routed in a serpentine manner to provide substantially the same actual trace length and signal delay between the register chip and the various stacks. However, the amount of such serpentine routing required to achieve balanced trace lengths is substantially less than the amount which would be required in a conventional DIMM module. This minimizes the amount of space on the base panel wasted in serpentine routing and helps to minimize the need for additional layers in the base panel to accommodate such routing.

Modules according to this aspect of the invention are readily scaleable. In particular, essentially any number of chips can be accommodated within each stack and the number of stacks can be varied. In a particularly preferred arrangement, a module using a relatively low number of chips in a stack as, for example, four chips per stack, is arranged with extra stack-mounting pads in the area occupied by each stack. These additional stack-mounting pads may be occupied by “dummy” or unused vertical buses in the four-stack embodiment, or may be left unoccupied simply by omitting the solder balls which constitute the dummy stacks. Stacks with more chips per stack as, for example, with eight chips per stack, require additional vertical select buses but do not require additional common buses. Thus, a larger stack can be mounted in the same location as the smaller stack; the additional vertical buses in the larger stack are connected to the pads which served as dummy stack-mounting pads in the embodiment using the smaller stack. The ability to provide for different numbers of chips per stack using the same module design simplifies design and manufacturing and also simplifies the design and manufacture of the larger circuit board which is used to mount the module. As further discussed below, the number of stacks per module likewise can be varied. Also, the additional chips provided on the bottom of the base panel can be included or omitted as desired. The additional chips can be used for error correction as discussed above, or can be used to provide additional memory capacity.

The preferred modules according to this aspect of the invention can be fabricated and can be mounted to a circuit board using standard surface-mounting techniques such as solder ball bonding. For example, as discussed in greater detail in the aforementioned co-pending applications, the preferred chip stacks can be fabricated using a large number of identical chip packages to constitute the units. In the assembled stack, the relatively few traces connecting the select contacts of each individual unit to the vertical buses of the stack differ from one another, whereas the traces associated with the common contacts are identical in all units. As also discussed in the aforementioned co-pending application, these differences can be introduced by breaking or connecting specially-configured traces associated with the select contacts. This simple customization process can be performed in the manufacturing facility which assembles the stack, which in turn can be the same manufacturing facility which assembles the module. Thus, only one type of packaged chip must be purchased, handled and stocked to make the stacks. Moreover, the identical type of packaged chip can be used as the additional chips. The ability to purchase and stock a single type of memory chip to form a module greatly simplifies manufacturing. The same single type of packaged memory chip can be used in modules of different sizes.

The module provides an extraordinarily compact memory unit. One measure of compactness is the ratio between the volume above the circuit board top surface occupied by the mounted module (hereinafter the “occupied volume”) and the volume of the actual memory chips themselves. The occupied volume is simply the product of the length and width of the base panel, (in directions parallel to and perpendicular to medial plane 21 in FIG. 1) and the occupied height ho (FIG. 4) or distance between the top surface of the circuit board and the highest point of the module, in this case, the top of stacks 32. Another measure of compactness is the volume of a theoretical rectangular solid which is just large enough to encompass the module itself, excluding the solder balls used to mount the module to the circuit board (hereinafter the “intrinsic volume”), i.e., the product of the length and width of the base panel and the height H_{I} (FIG. 4) from the bottom of the module itself to the top of the module. Additional measures of compactness are the ratio of the occupied volume to the total volume of the chips incorporated in the chip stacks and additional chips (hereinafter “working chip volume”), and the ratio of intrinsic volume to working chip volume. Each of these ratios desirably is about 15:1 or less, more preferably about 10:1 or less, and most desirably about 8:1 or less, with still smaller ratios being even more preferred.

In a module having the configuration depicted in FIGS. 1-4, using four stacks of eight memory chips of the type sold under the designation K4H5608380 by the Samsung company of South Korea, with one additional memory chip mounted beneath each stack on the bottom surface of the base panel, the aggregate volume of all thirty-six memory chips on the module is 1.2 cm³. The base panel is about 1.5 inches (38 mm) in length and width. With the module mounted to the circuit board using solder balls of a 1 mm (1000 micron) diameter, Hₒ is about 0.24 inches or 6.1 mm, so that the occupied volume is about 8,900 mm³ or about 8.9 cm³. The ratio of the occupied volume to working chip volume is about 7.4, whereas the ratio of intrinsic volume to working chip volume is about 6.4. By contrast, a conventional DIMM module mounting the same thirty-six chips uses a module board 5.25 inches (133.3 mm) long and 1.7 inches (43.18 mm) wide mounted on edge and projecting above the plane of the circuit board by a distance equal to the width of the module board. The memory chips are stacked to a thickness of approximately 0.26 inches (6.6 mm) in the direction perpendicular to the plane of the module board and, hence, the occupied volume is approximately 38,000 mm³ or 38 cm³. The memory module according to the aforementioned example of the invention occupies approximately one-fourth the volume of the conventional DIMM and holds the same memory devices while providing the same functions. Stated another way, the ratio of occupied volume to working chip volume in the aforementioned module according to an example of the invention is one-fourth the corresponding ratio in the conventional DIMM module. In general, ratio of occupied volume ratio to working chip volume in modules according to this aspect of the invention decreases with the number of chips in each stack and with the number of stacks in the module. However, a module substantially as illustrated in FIGS. 1-4, with four chips per stack and with one additional chip on the bottom surface of the base panel beneath each stack, has an occupied volume ratio of about 10, which is still superior to the occupied volume ratio of the DIMM with a larger number of memory chips. Stated another way, even using the less tightly packed four-chip stack variant, two modules according to FIGS. 1-4 holding forty memory chips in all, can be housed in less total occupied volume than a single DIMM module holding thirty-six memory chips.

Modules according to this aspect of the present invention provide good cooling for the various chips and particularly for the memory chips. The stacks of memory chips are exposed on at least two sides and, in the preferred arrangement depicted in FIGS. 1-4, on three sides of each stack. The channel 56 (FIGS. 3 and 4) overlying the central region 20 of the base panel provides for effective cooling from the inwardly-facing sides of the stacks, closest to the medial plane 21. Although some part of the channel is occupied by the control chips, the channel still provides for access of a cooling medium to the inwardly-facing sides of the stacks. Thermal modeling indicates that a module in accordance with the aforementioned examples, having four chips per stack, can be adequately cooled, so as to maintain temperatures within the stacks below about 60-61° C. using air at 40° C. (as prescribed by JEDEC standard test conditions simulating the environment inside a computer housing) with zero air flow velocity, or with forced flow at about 1 meter per second. Such an exemplary module dissipates about 6 to 8 watts of power.

Where more chips per stack are provided, it is desirable to cool the module using spray cooling or other techniques of enhanced heat transfer to a cooling medium. Certain spray cooling techniques are disclosed in U.S. Pat. Nos. 5,220,804 and 6,447,270, the disclosures of which are hereby incorporated by reference herein. Spray cooling techniques are commonly employed in cooling electronic systems which are particularly compact and which dissipate particularly large amounts of power per unit volume. Ordinarily, the spray cooling system is arranged to cool many components in the system. The design of the module in accordance with this aspect of the invention lends itself readily to use with spray cooling systems. For example, mounting of the module with the base panel parallel to the underlying circuit board exposes large surface areas of the chip stacks to contact with the spray. Also, the central channel 56 provides access for the spray to the inwardly-facing sides of the chip stacks. Moreover, because the module has a low height (ho) above the board, it does not substantially obstruct spray flowing to other parts of the board.

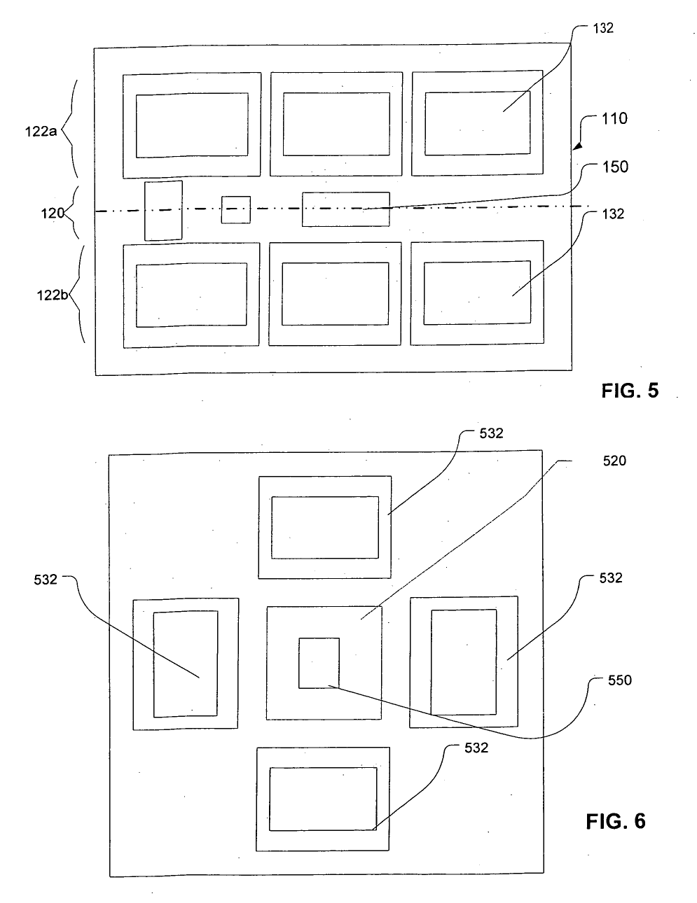

A module (FIG. 5) in accordance with a further embodiment of the invention includes a base panel 110, chip stacks 132 and control chips 150 similar to the corresponding features of the module discussed above with reference to FIGS. 1-4. However, the module of FIG. 5 incorporates six chip stacks 132, rather than four chip stacks. Here again, however, the modules are arranged in rows generally parallel to the medial plane 121 of the circuit panel, such that one row of chip stacks lies in a side region 122a of one side of the medial plane 121, whereas the opposite row lies in the opposite side region 122, on the opposite side of the medial plane and on the opposite side of central region 120. In a similar manner, modules with eight or more chip stacks can be fabricated. Where large numbers of chip stacks are employed, it may be desirable to use additional control chips as, for example, two register chips disposed adjacent opposite ends of central region 120. For example, a module incorporating eight stacks would be arranged essentially as two of the four-stack modules discussed above with reference to FIG. 1 formed on a common base panel.

A module according to a further embodiment (FIG. 6) includes a square base panel 510 having a central region 520 near the center of the panel and four chip stacks 532 disposed in four peripheral regions adjacent the four edges of the square. Here again, positioning the control chips, such as a register chip 550, in the central region 520 between the chip stacks, allows for relatively short trace lengths and balanced trace lengths without extensive serpentine routing.

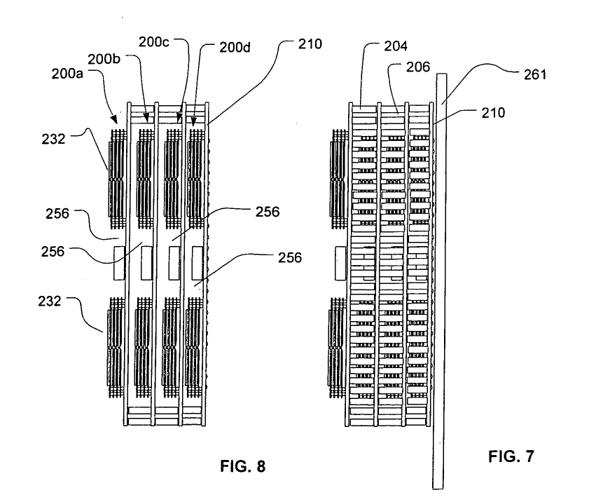

As shown in FIGS. 7 and 8, an assembly in accordance with a further embodiment of the invention includes a plurality of modules 200 superposed one atop the other in a stack of modules. Here again, each module includes a plurality of chip stacks 232 and each chip stack includes a plurality of chips stacked one atop the other, and each module 200 also includes a base panel 210 carrying the chip stacks. The base panel 210 of the lower-most module 200d in the stack desirably includes external terminals similar to the external terminals of the modules discussed above adapted for surface mounting, so that the entire assembly can be mounted on a circuit board 261 with the bottom surface of the lower-most module base panel facing downwardly toward the top surface of the circuit board 261. The modules are interconnected with one another by interconnect elements extending between the base panel 210 of each module, other than the lower-most module, and the next higher module in the stack. The interconnect elements may be in the form of generally columnar stand-offs or pillars formed from a metallic material. The base panel of each module may have external terminals exposed at the top and bottom surfaces of the base panel, so that the external terminals can be readily connected to the terminals of neighboring modules by the interconnect elements. The interconnect elements connect the base panels of the plural modules with one another in a manner similar to the way in which the conductive elements 46 (FIG. 4) in a chip stack connect the various chip carriers of the stack with one another.

Assemblies of this type can accommodate a large number of chips in a small volume and in a small area of the underlying circuit board. However, packing so many chips into such a small volume leads to relatively high heat dissipation per unit volume. The assembly according to this embodiment includes several features which aid in cooling the chips. The interconnect elements 204 desirably define gaps 206 between them so that coolant can flow through these gaps to each of the modules inside the stack. Moreover, as discussed above, each module desirably has chip stacks arranged in rows so that the chip stacks define one or more channels extending over the top surface of the circuit panel, between the rows of chip stacks as, for example, channels 256 between rows of chip stacks 232. These channels communicate with the gaps 206 between the connecting elements, so that coolant can flow through the assembly. The modules discussed above have the chip stacks within each row closely spaced, so that each module defines only one large channel extending parallel to the medial plane of the module as discussed above. However, the chip stacks can be spaced apart from one another in directions parallel to the medial plane so that the module defines plural channels extending in mutually perpendicular directions, i.e., parallel to the medial plane and perpendicular to the medial plane. Such additional channels can further promote cooling. Also, it may not be necessary to provide control chips within the channels of all of the modules or within all of the channels. This will further enhance coolant flow through the channels.

In the embodiments depicted in FIGS. 7 and 8, the chip stacks 232 are all disposed on the top surface of each module. Here again, the various modules may have additional chips disposed on the bottom surface, desirably in registration with the chip stacks on the top surface. In a further variant, chip stacks may be provided on both the top and bottom surfaces of the base panels of some or all of the modules. In still other variants, the base panels may be interconnected with one another by elements other than the discrete connecting elements 204 discussed above. For example, vertically extensive circuit panels (not shown) may be provided so that these panels extend between the various modules in the assembly. In yet another variant, the vertically extensive circuit panels may be integral with the base panels of the modules. Thus, the base panels of several modules can be fabricated as portions of an elongated, strip-like circuit panel which is entirely flexible or which has flexible portions therein, and such strip-like circuit panel can be folded back upon itself so as to superpose the base panels of the various panels on one another. Typically, this folding operation is performed after the chip stacks are assembled to the strip-like circuit panel. As disclosed, for example, in U.S. Pat. Nos. 6,121,676 and 6,225,688 and in commonly assigned co-pending U.S. patent application Ser. Nos. 10/077,388 and 10/236,442, the disclosures of which are hereby incorporated by reference herein, chips can be stacked upon one another to form a chip stack by attaching the chips to a flexible chip carrier in the form of an elongated strip or cruciform, and folding the chip carrier before or after attaching the chips. Similar folding approaches can be used to fabricate a stack of modules. In the folded-carrier chip stacks, each region of the folded chip carrier carries one or more semiconductor chips. In a folded-base-panel multi-module assembly according to this aspect of the present invention, each region of a folded module base panel carries a plurality of chip stacks, each such chip stack incorporating plural chips.

Numerous variations of the features of the modules and assemblies discussed above can be used. For example, the solder ball mountings used to hold the base panel to the circuit board in the embodiments discussed above with reference to FIGS. 1-4 can be replaced by other surface-mounting techniques such as land-grid arrays or column-grid arrays. In a further variant, the external terminals of the base panel can be arranged for mounting using techniques other than surface-mounting. For example, such external terminals may include pins so as to provide a pin-grid array suitable for use with sockets or other conventional mountings.

The individual chip stacks used in modules according to the aforementioned embodiments need not necessarily include separate chip carriers connected to one another by conductive elements as discussed above. Instead, each chip stack may be a folded-carrier chip stack as taught in one or more of the aforementioned patents and patent applications. Another form of chip stack which has been employed includes a plurality of chips superposed on one another and connected to a common chip carrier by conductors such as wire bonds or lead frames, the conductors from the higher chips in the stack extending downwardly past the lower chips in the stack or being connected together with the conductors from the lower chips in the stack. Chip stacks of this type are disclosed, for example, in U.S. Pat. Nos. 4,982,265 and 4,996,583, the disclosures of which are hereby incorporated by reference herein. Chip stacks of this type can be employed in modules according to the present invention. However, chip stacks of the general type discussed above with reference to FIGS. 1-4, incorporating separate chip carriers connected by conductive elements are preferred. As disclosed in the aforementioned U.S. patent application Ser. Nos. 10/267,450 and 10/454,029, chip stacks of this general type can be made either in a chip-up embodiment, with the chip associated with each carrier disposed above that carrier as depicted in FIG. 4, or in a chip-down embodiment, in which the chip associated with each carrier is disposed beneath that chip carrier. Either approach can be employed in accordance with the present invention. Moreover, each unit can include more than one chip mounted to the chip carrier of such unit.

The specific embodiments discussed above include memory chips in the chip stacks. However, chips other than memory chips also can be provided as stacks of chips, together with one or more additional chips which facilitate operation of the chips in the stacks. For example, a plurality of substantially identical microprocessors can be provided together with one or more additional chips which act to coordinate the actions of the plural microprocessors. Accordingly, the term “control chip” as used in the present disclosure should be understood as referring to a chip which is used to facilitate the operation of a plurality of other, chips incorporated in stacks, and as including, without limitation, the register, PLL and non-volatile memory discussed above in connection with DRAM chips. Modules according to this aspect of the present invention can include any type of semiconductor chips in the chip stacks, and can include or omit control chips. Further, where the chips in the stacks include DRAM chips, one or more of the specific control chips discussed above can be omitted.

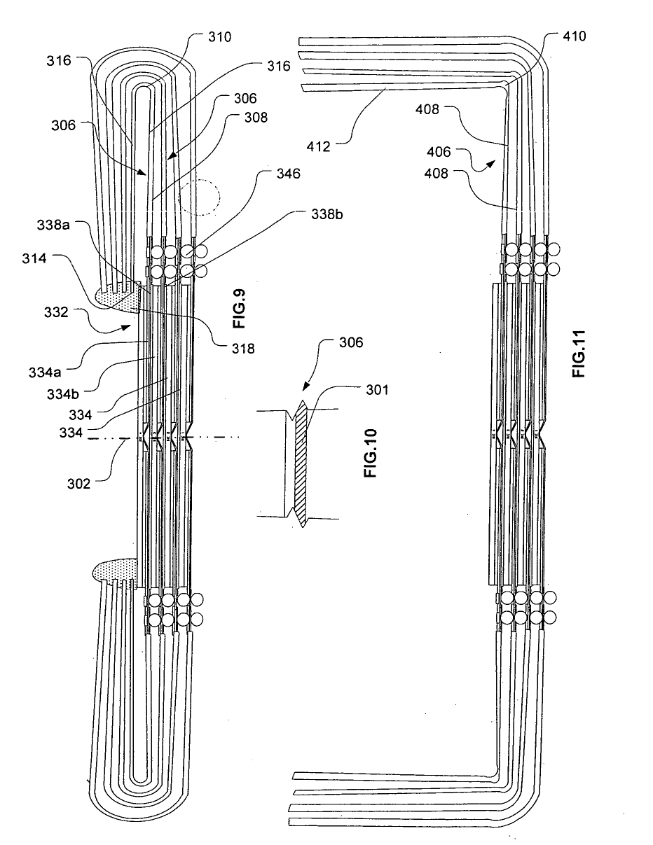

A chip stack or stacked chip assembly 332 according to a further aspect of the present invention is shown in FIG. 9. This chip stack, like the chip stacks discussed above, incorporates a plurality of individual units 334. Each unit includes a chip carrier 338 which may be generally similar to the chip carriers 38 discussed above with reference to FIG. 4. Each such chip carrier 338 may have a dielectric layer and traces on the dielectric layer at least in a central region of each chip carrier, relatively near to the center 302 of the chip carrier. The chip carriers bear chips 334 on this central region and, once again, the chip carriers are aligned with one another so that the various chips in the stack are aligned. In this embodiment as well, the traces of the various chip carriers are electrically connected to one another by conductive elements such as solder balls 346, also referred to as unit interconnecting elements. Thus, in this embodiment as well, the central portions of the chip carriers extend horizontally and are aligned with one another. In this embodiment, however, each chip carrier also includes a peripheral or extension region 306 extending outwardly (in the direction away from the central region and away from center 302 at one or more edges of the chip carrier. Each peripheral or extension region 306 incorporates an outwardly extending run 308 projecting generally in the plane of the central region to an outer-most extremity 310 at a maximum distance from the medial plane as measured along the surface of the chip carrier. Each extension region 306 also includes an inwardly extending run 312 extending from the outer-most extremity 310 inwardly toward the center and terminating at an inboard edge 314. The extension portions 306 of the chip carriers, like the other regions of the chip carriers, are generally planar or sheet-like. A major surface 316 of the chip carrier in the inward run 312 faces toward the same major surface 316 in the outward run 308. Most preferably, the chip carrier is simply folded on itself so as to define an end or bight at outer-most extremity 310. As seen in FIG. 9, the outer or extension regions of the chip carriers are nested within one another, so that the outer region 306 of the chip carrier 338a in the top-most unit 334a lies inside the outer or extension region 306 of the chip carrier 338b in the next adjacent unit, and so on. The inboard edges 314 of the various inward runs 312 desirably extend over the central regions of the chip carriers and over the chip in the top unit 334a. These inboard edges desirably are secured to the top unit 334 by a mass of a thermally-conductive adhesive material 318. As best seen in detail in FIG. 10, each extension portion. 306 incorporates a layer of a thermally-conductive material such as a metal 301. This metal layer may be provided as a portion of the same metallic layer used to form the traces and pads in the central region. As also shown in FIG. 9, a similar arrangement of outward extensions 306 may be provided at the opposite edge of each chip carrier. Moreover, extensions 306 may be provided at the other edges of the chip carrier, i.e., the edges facing into and out of the plane of the drawing in FIG. 9. The extension portions form an enhanced heat transfer structure. Heat can be conducted from within each stack out along the extension portions of the chip carriers and dissipated from the extension portions into the cooling medium. In effect, the extension portions serve as heat-dissipating fins. The arrangement shown in FIG. 9 is particularly effective where the coolant flow is directed into and out of the plane of the drawing as seen in FIG. 9, i.e., through the nested extension portions 306.

A chip stack in accordance with a further embodiment of the invention includes extension portions 406 having similar outward runs 408 extending away from the medial plane of the chip carriers. In this embodiment, however, each extension 406 has an upward or out-of-plane run extending from the outer extremity 410 of the outward run. Here again, the extension portions 406 incorporate thermally-conductive layers and, hence, act as cooling fins for the stack. Here again, the extension portions 406 are nested, so that major surfaces of adjacent extension portions confront one another.

In further embodiments, the extension portions may have other folded or convoluted configurations. Desirably, however, each extension portion includes at least one portion extending out of the plane of the central portion of the chip carrier. This arrangement helps to pack additional area for convective cooling into an extension portion of reasonable size.

Chip stacks discussed above with reference to FIGS. 9-11 can be employed as chip stacks in modules according to the other aspects of the invention or as portions of other assemblies.

As these and other variations and combinations of the features discussed above can be utilized without departing from the present invention as defined by the claims, the foregoing description of the preferred embodiments should be taken by way of illustration rather than by way of limitation of the invention as defined by the claims.

1. A module comprising:
(a) a base circuit panel having top and bottom surfaces and external terminals adapted for mounting said base circuit panel to an external circuit board, said base panel also having traces, said base panel including said base panel including peripheral regions and a central region disposed between said peripheral regions;
(b) at least four chip stacks, each said chip stack including a plurality of chips superposed on one another, said chip stacks being mounted on said top surface of said base circuit panel in said peripheral regions of said base panel; and
(c) a first control chip mounted to said base panel in said central region of said base panel, said traces on said base circuit panel including first control chip interconnect traces connecting said first control chip to said chip stacks, said chip stacks being arranged on said base panel so that each chip stack directly borders said central region.

2. A module as claimed in claim 1 wherein the center-to-center distance between each one of said chip stacks and said first control chip is no more than 2 times the center-to-center distance between any other one of said chip stacks and said first control chip.

3. A module as claimed in claim 1 wherein said chip stacks include a first pair of stacks disposed in a first row on a first side of said central region and a second pair of stacks disposed in a second row a second side of said central region opposite from said first side.

4. A module as claimed in claim 1 wherein said chip stacks cooperatively define a chip stack centroid, and wherein base panel has a set of chip stack pads associated with each of said chip stacks, each of said chip stacks being connected to said base panel by the associated set of chip stack pads, a subset of chip stack pads in each said set being connected to said first control chip, said subsets cooperatively defining a centroid of connected chip stack pads, said subset of connected chip stack pads being offset from said chip stack centroid in an offset direction, said first control chip being offset from said chip stack centroid in said offset direction.

5. A module as claimed in claim 1 further comprising additional chips, said additional chips being mounted to said bottom surface of said base panel.

6. A module as claimed in claim 5 wherein said additional chips are mounted to said bottom surface in alignment with said chip stacks.

7. A module as claimed in claim 5 wherein each of said stacks includes a plurality of units, each said unit including a chip and a chip carrier having pads, the units within each said stack having substantially identical arrangements of pads.

8. A module as claimed in claim 7 wherein the chip carriers of the units of all of said stacks have substantially identical arrangements of pads.

9. A module as claimed in claim 8 further comprising chip carriers associated with said additional chips, the chip carriers associated with said additional chips having pads arranged substantially identically to the pads of the chip carriers in said stacks.

10. A module as claimed in claim 5 wherein said external terminals are exposed at said bottom surface of said base panel in regions of said base panel unoccupied by said additional chips.

11. A module as claimed in claim 1 wherein said external terminals are exposed at said bottom surface of said base panel.

12. A module as claimed in claim 11 wherein said external terminals are adapted for surface-mounting said base panel to an external circuit board.

13. A module as claimed in claim 1 wherein said chips in said chip stacks are memory chips.

14. A module as claimed in claim 13 wherein said chips in said chip stacks are DRAM chips.

15. A module comprising:
(a) a base panel having a top surface, said base panel including a central region and first and second side regions disposed on opposite sides of said central region;
(b) a plurality of chip stacks, said chip stacks being arranged in a first row including at least two chip stacks projecting upwardly from said top surface in said first side region and a second row of chip stacks projecting upwardly from said top surface in said second side region, said second row of chip stacks extending generally parallel to said first row of chip stacks, whereby said rows of chip stacks define a channel extending across said central region in a channel direction generally parallel to said first and second rows.

16. A module as claimed in claim 15 further comprising a first control chip mounted on said central region of said base panel, said panel having first control chip interconnect traces interconnecting said first control chip with said chip stacks.

17. A module as claimed in claim 16 wherein said first control chip is mounted on said top surface of said base panel so that said first control chip is disposed in said channel.

18. A module as claimed in claim 17 wherein said first control chip has a lesser height above said top surface than said chip stacks so that a portion of said channel above said first control chip remains open.

19. A module as claimed in claim 17 further comprising a second control chip mounted on said top surface in said channel.

20. A module as claimed in claim 15 wherein said base panel has a bottom surface and external terminals adapted for mounting the base panel to an external circuit board so that the base panel overlies the external circuit board with said bottom surface facing toward the external circuit board.

21. A module as claimed in claim 20 wherein said external terminals are exposed at said bottom surface of said base panel.

22. A module as claimed in claim 21 wherein said external terminals are adapted for surface-mounting said base panel to an external circuit board.

23. An assembly comprising:
(a) a plurality of modules, each said module including a base panel having top and bottom surfaces and a plurality of chip stacks mounted on the top surface of the base panel;
(b) interconnect elements physically connecting the base panels of said modules to one another so that said modules are arranged in a vertically-extensive module stack with said base panels superposed over one another and each said base panel extending generally horizontally; and
(c) assembly terminals adapted for mounting said module stack to an external circuit board with said module stack projecting upwardly from said circuit board.

24. An assembly as claimed in claim 23 wherein the base panel of a bottom one of said modules disposed at the bottom of the module stack has said assembly terminals exposed at the bottom surface of that base panel.

25. An assembly as claimed in claim 24 wherein said interconnect elements include a plurality of electrically conductive elements extending between the base panels of adjacent modules in said module stack.

26. An assembly as claimed in claim 25 wherein the interconnect elements extending between each pair of adjacent modules define gaps therebetween.

27. An assembly as claimed in claim 26 wherein, in at least some of said modules, said chip stacks are disposed in a plurality of rows defining at least one channel between adjacent rows, and said channels communicate with at least some gaps between interconnect elements so that said channels and gaps provide paths through said module stack.

28. A module comprising:
(a) a base panel having a bottom surface, a top surface, traces and a plurality of external terminals adapted for mounting the base panel on an external circuit board;
(b) a plurality of chip stacks mounted on said top surface, each such stack including a plurality of memory chips, and
(c) one or more control chips mounted to said base panel,
said module having a ratio of intrinsic volume to working chip volume of about 15 or less.

29. A module as claimed in claim 28 wherein said ratio of intrinsic volume to working chip volume is about 10 or less.

30. A method of making a plurality of multichip module comprising:
(a) providing a plurality of units, each including a chip and a chip carrier, the chip carriers of said units having pads disposed in arrays, the pad arrays of said of said units being substantially identical to one another;
(b) forming chip stacks from some of said units by interconnecting corresponding pads on a plurality of said units with one another to form vertical buses;
(c) mounting said chip stacks to top surfaces of a plurality of base circuit panels; and
(d) mounting others of said units individually to bottom surfaces of at least some of said plurality of base circuit panels.

31. A method as claimed in claim 30 said providing step includes providing each of said units with traces connecting the pads of such unit with the chip of such unit, the traces of each said unit being substantially identical to the traces of the other units, the method further including the step of modifying at least one trace of at least some of said units.

32. A method as claimed in claim 31 wherein said stack-forming, stack-mounting, individual unit mounting and modifying steps are all performed in the same production facility.

33. A method as claimed in claim 30 wherein said individual unit mounting step is performed for less than all of said base circuit panels.

34. A stacked chip assembly comprising:
(a) a plurality of units, each said unit incorporating a chip carrier having oppositely-directed major surfaces, a generally planar central region and a peripheral region, and a chip mounted to said central region; and
(b) unit interconnecting elements electrically interconnecting said units in a vertically-extensive stack so that said units are superposed, one above the other with the central regions of said chip carriers extending horizontally and being aligned with one another;
at least some of said peripheral regions of said chip carriers being curved peripheral regions, each such curved peripheral region extending out of the plane of the central region.

35. A stacked chip assembly as claimed in claim 34 wherein each said curved peripheral region includes an outward run extending outwardly from said stack, a bight at an outboard end of the outward run extending around a horizontal axis and an inward run extending from the bight inwardly to an inboard end adjacent the stack.

36. An assembly as claimed in claim 35 wherein the inboard edges of said curved peripheral regions extend over the top of the stack.

37. An assembly as claimed in claim 34 wherein a curved peripheral region of a first one of said chip carriers is nested within a curved peripheral region of a second one of said chip carriers so that major surfaces of said nested peripheral regions confront one another.

38. An assembly as claimed in claim 37 wherein said nested curved peripheral regions define coolant passages between them.

39. An assembly as claimed in claim 34 wherein said curved peripheral regions include metallic thermal conductors.
